(19) United States
(12) Patent Application Publication
(10) Pub. No.: US 2023/0142924 A1
(43) Pub. Date: May 11, 2023

(54) 3D NAND MEMORY DEVICE AND FORMING METHOD THEREOF

(71) Applicant: YANGTZE MEMORY TECHNOLOGIES CO., LTD., Wuhan (CN)

(72) Inventors: Haojie Song, Wuhan (CN); Qian Gao, Wuhan (CN); Kun Bao, Wuhan (CN); Huan He, Wuhan (CN); Yajun Huang, Wuhan (CN); Yansan Ma, Wuhan (CN)

(21) Appl. No.: 18/090,440

(22) Filed: Dec. 28, 2022

Related U.S. Application Data
(63) Continuation of application No. PCT/CN2021/124789, filed on Oct. 19, 2021.

(30) Foreign Application Priority Data
Oct. 19, 2020 (CN) 202011117206.4

(51) Int. Cl. H10B 41/27; H10B 41/35; H10B 43/27; H10B 43/35; H01L 23/522; H01L 23/528

(52) U.S. Cl. CPC H10B 41/27; H01L 23/5226; H01L 23/5283; H10B 41/35; H10B 43/27; H10B 43/35

(57) ABSTRACT

A method for forming a 3D NAND memory device is provided. The method includes: providing a semiconductor structure including a semiconductor substrate, a stacked structure, and a dielectric layer covering the semiconductor substrate and the stacked structure; forming, in the dielectric layer and the stacked structure, channel through vias penetrating through the stacked structure; forming a channel structure in each channel through via, and sequentially forming a polysilicon layer, a first metal silicide layer located on the polysilicon layer, and a through via contact metal layer located on the first metal silicide layer in the channel structure; forming a first through via in the dielectric layer for exposing the semiconductor substrate after forming the first metal silicide layer; forming a second metal silicide layer at a bottom of the first through via; and forming a first contact plug connected to the second metal silicide layer in the first through via.

### CROSS-REFERENCE TO RELATED APPLICATIONS

This application is a continuation of International Application No. PCT/CN2021/124789 filed on Oct. 19, 2021. which claims the benefit of priority to Chinese Application No. 202011117206.4 filed on Oct. 19, 2020, the contents of which are hereby incorporated by reference in their entireties.

### BACKGROUND

A NAND flash memory is a better storage device than hard disk drives . As people pursue non-volatile storage products with low power consumption, light weight, and good performance, the non-volatile storage products have been widely used in electronic products. At present, a NAND flash memory with a planar structure is close to the limit of actual expansion. In order to further increase the storage capacity and reduce the storage cost per bit, a NAND memory with a 3D structure is proposed.

### SUMMARY

The present disclosure provides a method for forming the 3D NAND memory device, which includes the following steps.

A semiconductor substrate is provided, the semiconductor substrate has a well region, a stack structure including alternately stacked sacrificial layers and isolation layers on the well region of the semiconductor substrate, and a staircase structure at an end of the stacked structure.

A dielectric layer covering the semiconductor substrate and the stacked structure is formed.

Channel through vias penetrating through the stacked structure are formed in the dielectric layer and the stacked structure.

A storage structure and a polysilicon layer located on the storage structure are formed in the channel through via, the surface of the polysilicon layer is lower than the top surface of the dielectric layer.

A first metal silicide layer on the surface of the polysilicon layer and a through via contact metal layer located on the first metal silicide layer are formed.

The sacrificial layer is replaced with a gate line.

A first through via exposing a part of the surface of the well region on one side of the stacked structure and a number of second through vias exposing the surface of the corresponding staircase structure are formed in the dielectric layer.

A second metal silicide layer is formed on the surface of the well region at the bottom of the first through via.

A first contact plug connected to the second metal silicide layer is formed in the first through via, and a second contact plug connected to the surface of the corresponding staircase structure is formed in the second through via.

In some implementations, the formation process of the first metal silicide layer and the through via contact metal layer may be as follows: a first metal layer is formed on a surface of the dielectric layer and in the channel through via on the polysilicon layer; the first metal layer is annealed to make the first metal layer react with part of the polysilicon layer on the channel structure to form a first metal silicide on a surface of the polysilicon layer, the surface of the first metal silicide layer is lower than the top surface of the dielectric layer; the unreacted first metal layer is removed and a through via contact metal layer is formed on the surface of the first metal silicide layer, the surface of the through via contact metal layer is flush with the top surface of the dielectric layer.

In some implementations, the material of the first metal silicide layer may be one or a combination of nickel silicide, cobalt silicide, tantalum silicide, or titanium silicide.

In some implementations, the formation process of the gate line may be as follows: a hard mask layer is formed on the stacked structure; a gate line slit is formed in the hard mask layer and the stacked structure: the sacrificial layer is removed along the gate line slit; a gate line is formed at a position where the sacrificial layer is removed; and an array common is formed in the gate line slit.

In some implementations, the method may further include as follows: a bit line connected to the through via contact metal layer is formed in the hard mask layer, and the size of the bit line is less than the size of the through via contact metal layer.

In some implementations, the formation process of the second metal silicide layer, the first contact plug, the second contact plug and the bit line contact may include the following steps: the hard mask layer and a dielectric layer are etched, a first through via exposing part of the surface of the well region on one side of the stacked structure and a number of second through vias exposing the surface of the corresponding staircase structure are formed in the hard mask layer and the dielectric layer, and a third through via exposing a part of the surface of the through via contact metal layer is formed in the hard mask layer, the size of the third through via is less than the size of the through via contact metal layer; a second metal layer is formed in the first through via and on the surface of the hard mask layer; annealing is performed to make the second metal layer react with silicon in the well region to form a second metal silicide layer on the surface of the well region; the unreacted second metal layer is removed; the first through via, the second through via, and the third through via are filled with a metal layer, a first contact plug connected to the second metal silicide layer is formed in the first through via, a second contact plug connected to the surface of the corresponding staircase structure is formed in the second through via, and a bit line connected to the through via contact metal layer is formed in the third through via.

In some implementations, the material of the second metal silicide layer may be one or a combination of nickel silicide, cobalt silicide, tantalum silicide, and titanium silicide.

In some implementations, the storage structure may include a charge storage layer located on the sidewall surface of the channel through via and a channel layer located on the sidewall surface of the charge storage layer.

In some implementations, the charge storage layer may include a barrier layer located on the sidewall surface of the channel through via, a charge trapping layer located on the sidewall surface of the barrier layer, and a tunneling layer on the sidewall surface of the charge trapping layer.

In some implementations, the gate line may include a gate dielectric layer and a gate electrode located on the gate dielectric layer.

Furthermore, the formation process of the second metal silicide layer, the first contact plug, the second contact plug and the bit line contact may include the following steps: the hard mask layer and a dielectric layer are etched, a first through via exposing part of the surface of the well region on one side of the stacked structure and a number of second through vias exposing the surface of the corresponding staircase structure are formed in the hard mask layer and the dielectric layer, and a third through via exposing a part of the surface of the through via contact metal layer is formed in the hard mask layer, the size of the third through via is less than the size of the through via contact metal layer; a second metal layer is formed in the first through via and on the surface of the hard mask layer: annealing is performed to make the second metal layer react with silicon in the well region to form a second metal silicide layer on the surface of the well region; the unreacted second metal layer is removed; the first through via, the second through via, and the third through via are filled with a metal layer, a first contact plug connected to the second metal silicide layer is formed in the first through via, a second contact plug connected to the surface of the corresponding staircase structure is formed in the second through via, and a bit line connected to the through via contact metal layer is formed in the third through via

### BRIEF DESCRIPTION OF THE DRAWINGS

FIGS. 1A-1D illustrate schematic diagrams of respective cross-sectional structures in a formation process of a 3D NAND memory device.

FIGS. 2-10 illustrate schematic diagrams of respective cross-sectional structures in a formation process of a 3D NAND memory device according to some implementations of the present disclosure.

### DETAILED DESCRIPTION

As mentioned in the background art, the thickness of the first metal silicide layer formed in the related art is difficult to meet the performance requirements.

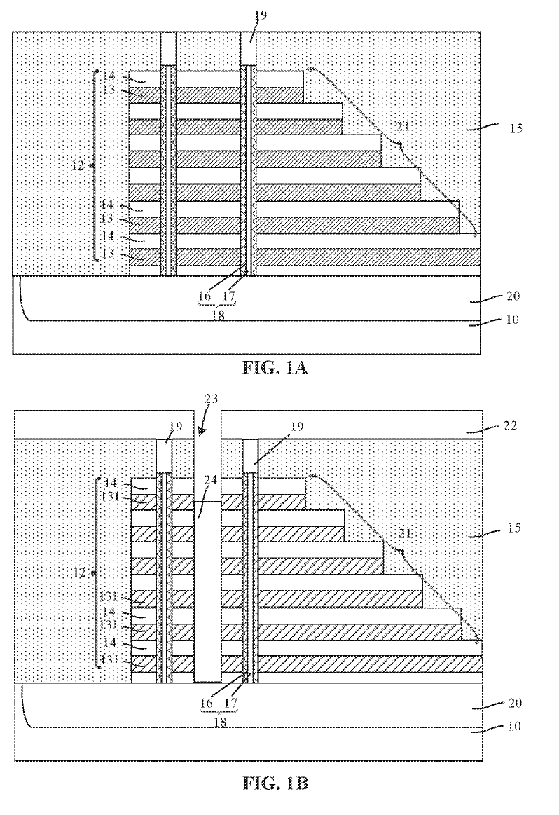

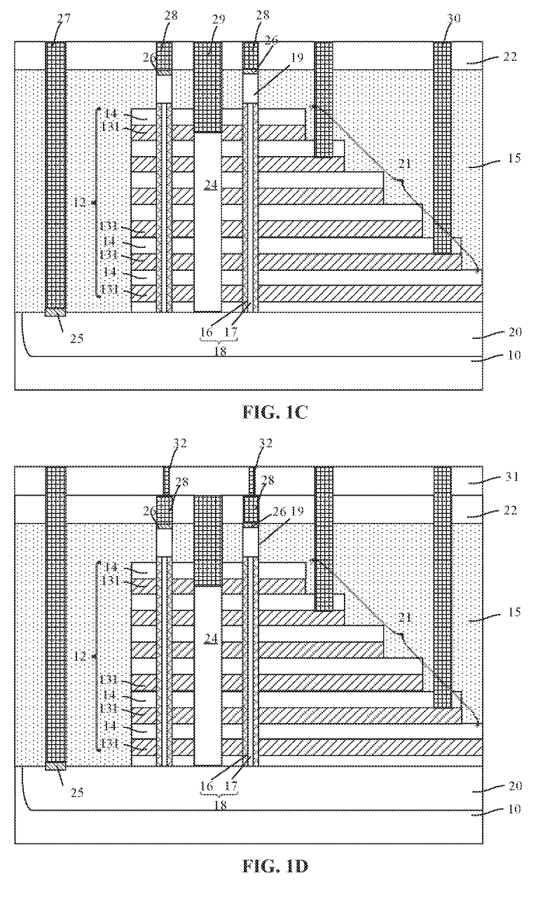

FIGS. 1A-1D illustrate schematic diagrams of respective cross-sectional structures in a formation process of a 3D NAND memory device. Referring to FIG. 1A, a semiconductor structure is provided. The semiconductor structure includes a semiconductor substrate 10, a stacked structure 12, a first dielectric layer 15, a channel through via, a channel structure 18. and a polysilicon layer 19. The semiconductor substrate has a well region 20, the semiconductor substrate 10 has a stacked structure 12 in which sacrificial layers 13 and isolation layers 14 are alternately stacked, and one end of the stacked structure 12 has a staircase structure 21. The first dielectric layer 15 covers the stacked structure 12 and the semiconductor substrate 10 on one side of the stacked structure 12. The channel through via penetrates through the first dielectric layer 15 and the stacked structure 12, the channel structure 18 is located in the channel through via, and the polysilicon layer 19 is located in the remaining channel through vias on the channel structure 18. The channel structure 18 includes a charge storage layer 17 on the sidewall surface of the channel through via and a channel layer 16 located on the surface of the charge storage layer 17.

Referring to FIG. 1B, a mask layer 22 is formed on the stacked structure 12: a gate line slit (GLS) 23 is formed in the mask layer 22 and the stacked structure 12; a dielectric material layer (e.g., oxide sidewall) is formed in the gate line slit 23; the sacrificial layer is removed along the gate line slit 23; a gate line 131 is formed at a position where the sacrificial layer is removed. An array common source (ACS) 24 is formed in the gate line slit 23 (e.g., in the gate line slit 23 where the oxide sidewall is formed). The material of the mask layer 22 may be the same as the material of the dielectric material layer formed in the gate line slit 23.

Referring to FIG. 1C, a first through via which exposes a part of the surface of the well region 20 on one side of the stacked structure 12 and a number of second through vias that expose the surface of the corresponding staircase structure 21 are formed in the mask layer 22 and the first dielectric layer 15 by a first photolithography process, and a bit line contact through via exposing the polysilicon layer 19 is formed in the mask layer 22. A first metal silicide layer 26 and a second metal silicide layer 25 are respectively formed in the bit line contact through via and the first through via. Since a lower contact resistance is required when a first contact plug 27 is connected to the well region, more metal needs to be deposited when forming the second metal silicide layer 25 to form a thicker second metal silicide layer 25. The hole depth on the channel structure is relatively shallow, and if the same amount of metal is deposited in the same process step, the thickness of the first metal silicide layer 26 formed by annealing in the bit line contact through via will be thicker. However, the inventor of the present disclosure has noticed in research that when the first metal silicide layer is formed on a channel hole in the related art, it is easy to form a void at a conductive plug of the channel hole, which causes the contact resistance to increase, which leads to a small overall channel current and degrades the low-temperature characteristics of the device.

The first through via, the second through via, the bit line contact through via, and the remaining gate line slit on the array common source 24 is filled with a metal layer material to form a first contact plug 27, a second contact plug 30, a bit line contact plug 28 and a fourth contact plug 29. Since the bit line contact through via and the first through via are formed in the same step, the diameter of the bit line contact through via may be different from the diameter of the polysilicon layer 19, for example, the diameters of the bit line contact through via and the bit line contact plug 28 are smaller than the diameter of the polysilicon layer 19.

Referring to FIG. 1D, a second dielectric layer 31 is formed on the mask layer 22, and a fourth through via exposing the bit line contact plug 28 is formed in the second dielectric layer 31 through a second photolithography process. In order to reduce the diameter of the bit line contact formed in the fourth through via, for example, to be smaller than the diameter of the channel through via or the first metal silicide layer, the diameter of the formed fourth through via is less than that of the bit line contact through via, a conductive material is filled in the fourth through via to form a bit line contact 32, and the diameter of the finally formed bit line contact 32 is less than the diameter of the channel through via or the first metal silicide layer. The bit line contact 32 is in conductive contact with the first metal silicide layer 26 through the bit line contact plug 28.

The inventors of the present disclosure have discovered through research that the thickness of the first metal silicide layer formed in the related art is too thick to meet the performance requirements. With further research, it has been found that the existing first metal silicide layer and second metal silicide layer are formed in the same process step. However, since a lower contact resistance is required when the first contact plug is connected to the well region, more metal needs to be deposited to form a thicker second metal silicide layer when forming the second metal silicide layer. As for the depth of the first through via, the hole depth of the bit line contact through via on the channel structure is shallower. If the same amount of metal is deposited in the same process step, the thickness of the first metal silicide layer formed by annealing in the bit line contact through via with a shallower hole depth will be thicker, that is, the thickness of the first metal silicide layer formed in the bit line contact through via with a shallower hole depth is greater than the thickness of the second metal formed in the first through via with a deeper hole depth. As a result, a void is prone to be formed at the conductive plug of the channel hole, which causes the contact resistance to increase, resulting in the problem of low overall channel currents and degeneration of the low-temperature characteristics of the device.

In addition, in order to make the size of the bit line contact smaller than the size of the channel through via or the first metal silicide layer, an additional photolithography process is required (a photolithography process is required to form the first through via and the third through via, a first metal silicide layer and a second metal silicide layer are formed in the first through via and the third through via respectively, the photolithography process needs to be done again when forming the bit line contact through via) to form a bit line contact with a size smaller than the size of the channel through via or the first metal silicide layer, which increases the cost. For example, the photolithography process for forming the bit line contact is not compatible with the photolithography process for forming the first metal silicide layer and the second metal silicide layer.

For example, the present disclosure provides a method for forming the 3D NAND memory device. In the method, a storage structure and a polysilicon layer located on the storage structure are formed in a channel through via, the surface of the polysilicon layer is lower than the top surface of the dielectric layer, a first metal silicide layer and a through via contact metal layer located on the first metal silicide layer are formed on the surface of the polysilicon layer, the sacrificial layer is replaced with a gate line, a first through via exposing part of the surface of the well region on one side of the stack structure and a number of second through vias exposing the surface of the corresponding staircase structure are formed in the dielectric layer, a second metal silicide layer is formed on the surface of the well region at the bottom of the first through via, a first contact plug connected to the second metal silicide layer is formed in the first through via, and a second contact plug connected to the surface of the corresponding staircase structure is formed in the second through via The step of forming the first metal silicide layer and the subsequent step of forming the second metal silicide layer are not performed in the same step, and therefore, when the first metal silicide is formed, the thickness of the formed first metal silicide layer may be adjusted separately so that the thickness of the first metal silicide layer is not limited by the process of forming the second metal silicide layer, so that the thickness of the formed first metal silicide layer meets the performance requirements, thus reducing the probability of occurrence of holes in the first metal silicide layer and further reducing the probability of increased contact resistance and decreased yield.

To promote the understanding of the objectives, features, and advantages of the present disclosure, implementations of the present disclosure will be described in detail below with reference to the accompanying drawings. When describing the implementations of the present disclosure in detail, for ease of description, the schematic diagrams will not be partially enlarged according to the general scale, and the schematic diagrams are only examples, which should not limit the protection scope of the present disclosure herein. In addition, the three-dimensional dimensions of length, width, and depth should be included in the actual production.

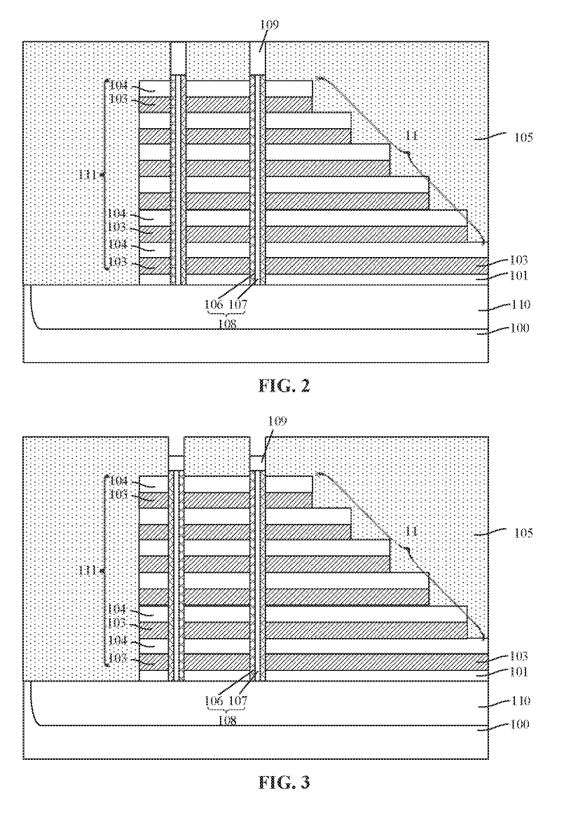

FIGS. 2-10 illustrate schematic diagrams of respective cross-sectional structures in a formation process of a 3D NAND memory device according to some implementations of the present disclosure.

It is to be noted that the method for forming the 3D NAND memory device described in the present disclosure is not limited to being used to form 3D NAND memory device, or may be used to form three-dimensional non-volatile memory such as 3D Re-RAM memory and 3D PCM memory.

Referring to FIG. 2, a semiconductor layer is provided. For example, the semiconductor layer may be a semiconductor substrate 100. For the convenience of description, the semiconductor layer will be described as the semiconductor substrate 100 later, but the implementations of the present disclosure are not limited thereto. For example, the semiconductor substrate 100 has a well region 110, a stacked structure 111 in which sacrificial layers 103 and isolation layers 104 are alternately stacked is formed on the well region 110 of the semiconductor substrate, and the end of the stacked structure 111 has a staircase structure 11; a dielectric layer 105 for covering the semiconductor substrate 100 and the stacked structure 111 is formed; channel through vias penetrating through the thickness of the stacked structure are formed in the dielectric layer 105 and the stacked structure 111: a storage structure 108 and a polysilicon layer 109 located on the storage structure 108 are formed in the channel through via. In some examples, each channel through via is provided with a channel structure, and the channel through via and the channel structure form a channel hole. Here, the storage structure 108 is a channel structure.

For example, the material of the semiconductor layer (semiconductor substrate 100) may include any one or any combination of single-crystal silicon (Si), single-crystal germanium (Ge), silicon germanium (GeSi), silicon carbide (SiC), or polysilicon: the material may also be silicon-on-insulator (SOI) or germanium-on-insulator (GOI): or may be other materials, such as group III-V compounds, for example, gallium arsenide. For example, the material of the semiconductor substrate 100 is single-crystal silicon (Si).

There is a well region 110 in the semiconductor substrate 100. The well region 110 may be a P-type well region. For example, the well region 110 may be a N-type well region.

The stacked structure 111 includes a number of alternately stacked sacrificial layers 103 and isolation layers 104 (e.g., electrical isolation layers, insulating layers). The sacrificial layers 103 are subsequently removed to form a cavity, and then gate lines are formed at the positions where the sacrificial layers 103 are removed. The isolation layer 104 serves as electrical isolation between the controlling gates of different layers, and between the controlling gates and other devices (conductive contact portion, channel holes, etc.). In some implementations, the sacrificial layer may include a dielectric material, a semiconductor material, or a conductive material. The isolation layer may include an electrical isolation material, an insulating material, or a dielectric material.

The sacrificial layer 103 and the isolation layer 104 are alternately stacked, including the sacrificial layer 103 and the isolation layer 104 are alternately arranged. In a specific implementation, the alternate stacking of the sacrificial layer 103 and the isolation layer 104 may be that after a sacrificial layer 103 is formed, a layer of isolation layer 104 is formed on the surface of the sacrificial layer 103, and then the steps of forming the sacrificial layer 103 and the isolation layer 104 on the sacrificial layer 103 are repeated sequentially. For example, the bottommost layer of the stacked structure 111 is a layer of sacrificial layer 103, and the topmost layer is an isolation layer 104. a buffer oxide layer 101 is also formed between the bottommost layer of the stacked structure 111 and the semiconductor substrate 100.

In an implementation, a buffer oxide layer 101 is further formed between the stacked structure 111 and the semiconductor substrate 100.

The number of layers in the stacked structure 111 (the number of layers in the double-layer stacked structure of the sacrificial layer 103 and the isolation layer 104 in the stacked structure 111) is determined according to the number of memory cells that need to be formed in the vertical direction. The number of layers in the stacked structure 111 may be 8, 32, 64, etc. The more the number of layers in the stacked structure 111, the more the integration can be improved. In this implementation, an example in which the number of layers of the stacked structure 111 is 6 will be described.

The material of the sacrificial layer 103 is different from the material of the isolation layer 104. When the sacrificial layer 103 is subsequently removed, the sacrificial layer 103 has a high etching selection ratio relative to the isolation layer 104. Therefore, when the sacrificial layer 103 is removed, the etching amount of the isolation layer 104 is small or negligible to ensure the flatness of the isolation layer 104.

The material of the isolation layer 104 may be one of silicon oxide, silicon nitride, silicon oxynitride, or silicon carbide nitride, and the material of the sacrificial layer 103 may be any one of silicon oxide, silicon nitride, silicon oxynitride, carbon nitride, amorphous silicon, amorphous carbon, or polysilicon. In this implementation, the material of the isolation layer 104 is silicon oxide, the material of the sacrificial layer 103 is silicon nitride, and the isolation layer 104 and the sacrificial layer 103 are formed by a chemical vapor deposition process.

In an implementation, the bottommost layer of the sacrificial layer 103 in the stacked structure 111 may be taken as the bottom selective gate sacrificial layer. Subsequently, the bottom selective gate (BSG) may be correspondingly formed at the position where the bottom selective gate sacrificial layer is removed. The topmost layer of sacrificial layer 103 in the first stacked structure 111 is taken as the top selective gate sacrificial layer, and subsequently, a top selective gate (TSG) is correspondingly formed at the position where the top selective gate sacrificial layer is removed.

In an implementation, one end of the stacked structure 111 has a staircase structure 11, and the staircase structure 11 includes a number of steps gradually raised in a stepped shape.

The top surface of the dielectric layer 105 is higher than the top surface of the stacked structure 111. The material of the dielectric layer 105 is silicon oxide. For example, the formation process of the dielectric layer 105 may be plasma enhanced chemical vapor deposition process, atmospheric pressure chemical vapor deposition process, low-pressure chemical vapor deposition process, high-density plasma chemical vapor deposition process, or atomic layer chemical vapor deposition process.

In an implementation, after channel through vias are formed in the dielectric layer 105 and the stacked structure 111, the semiconductor substrate 100 exposed at the bottom of the channel through vias is etched continuously to form a groove in the semiconductor substrate 100. A semiconductor epitaxial layer is formed in the groove by a selective epitaxial process. For example, the surface of the semiconductor epitaxial layer is lower than the surface of the bottommost isolation layer 104 and higher than the surface of the semiconductor substrate 100. The material of the semiconductor epitaxial layer is silicon, germanium, or silicon germanium; a storage structure 108 is formed on the semiconductor epitaxial layer. The surface of the storage structure 108 is lower than the surface of the dielectric layer 105. A polysilicon layer 109 that fills the remaining channel through vias is formed on the storage structure 108. For example, the surface of the polysilicon layer 109 is flush with the surface of the dielectric layer 105. A channel structure is provided in each channel through via, and the channel through via and the channel structure form a channel hole. Here, the storage structure 108 is a channel structure.

The storage structure 108 includes a charge storage layer 107 on the surface of the sidewall of the channel through via and a channel layer 106 on the surface of the charge storage layer 107. In some implementations, the charge storage layer 107 may be a charge storage functional layer, and the charge storage functional layer includes a stacked charge barrier layer, a charge trapping layer, and a tunneling layer. The method for forming the charge storage functional layer includes the steps of: a charge barrier layer is formed on the sidewall surface of the channel through via; a charge trapping layer is formed on the surface of the charge barrier layer; and a tunneling layer is formed on the surface of the charge trapping layer. The material of the charge barrier layer and the tunneling layer may be the same. For example, the material of the charge barrier layer and the tunneling layer is a silicon oxide layer, and the material of the charge trapping layer is a silicon nitride layer

In an implementation, the charge storage layer 107 includes a barrier layer located on the sidewall surface of the channel through via, a charge trapping layer located on the sidewall surface of the barrier layer, and a tunneling layer located on the sidewall surface of the charge trapping layer. The material of the barrier layer and the tunneling layer is silicon oxide, the material of the charge trapping layer is silicon nitride, and the material of the channel layer 106 is polysilicon.

Referring to FIG. 3, the polysilicon layer 109 is etched back so that the surface of the remaining polysilicon layer 109 is lower than the surface of the dielectric layer 105.

The etching back of the polysilicon layer may adopt a wet etching process or an isotropic plasma etching process. In some implementations, the polysilicon layer may be etched back through an etching process, so that the surface of the remaining polysilicon layer 109 is lower than the surface of the dielectric layer 105, thereby forming a recess in the polysilicon layer of the channel through via. In the process of etching back the polysilicon layer, the etching rate of the selected etching material for the polysilicon layer is greater than the etching rate for the dielectric layer 105. In this case, the dielectric layer 105 and the charge storage functional layer (tunneling layer) of the channel structure may be taken as an etching barrier layer for etching the polysilicon layer, so that the polysilicon layer may be etched without using an additional mask layer, thereby reducing the number of mask plates required for the process. Then, the first metal silicide layer and the through via contact metal layer may be formed in the recess subsequently. Here, the through via contact metal layer may be a bit line contact plug.

Etching back of the polysilicon layer 109 may be used to subsequently form the first metal silicide layer and the position of the through via contact metal layer located on the first metal silicide layer. In the implementations of the present disclosure, the first metal silicide layer and the through via contact metal layer (bit line contact plug) are formed in the channel through via. For example, the diameter of the through via contact metal layer is equal to the diameter of the polysilicon layer 109. For example, the diameter of the through via contact metal layer is equal to the diameter of the first metal silicide layer.

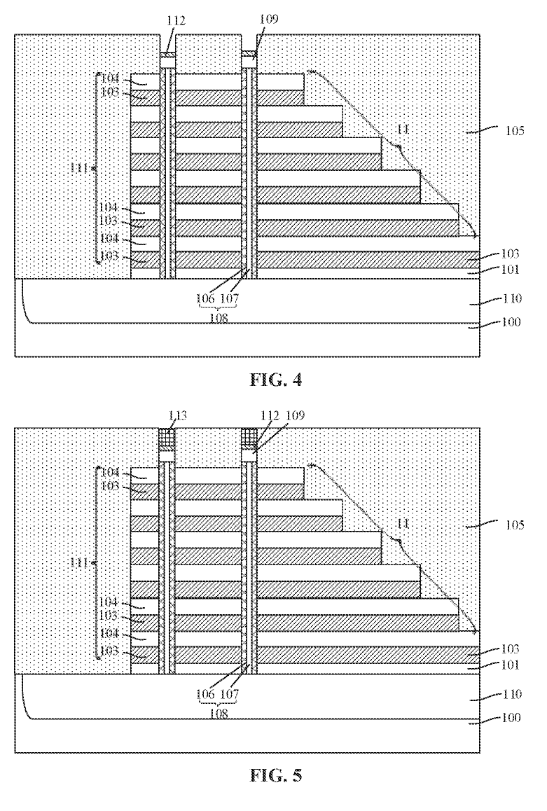

Referring to FIGS. 4 and 5, a first metal silicide layer 112 (referring to FIG. 4) and a through via contact metal layer 113 located on the first metal silicide layer 112 (referring to FIG. 5) are formed on the surface of the polysilicon layer 109.

In an implementation, the formation process of the first metal silicide layer 112 and the through via contact metal layer 113 is as follows: a first metal layer (not illustrated in the figure) is formed in the channel through via on the surface of the dielectric layer 105 and the polysilicon layer 109; the first metal layer is annealed to make the first metal layer react with part of the polysilicon layer 109 on the channel structure to form a first metal silicide 112 on the surface of the polysilicon layer 109. the surface of the first metal silicide layer 112 is lower than the top surface of the dielectric layer 105: the unreacted first metal layer is removed and a through via contact metal layer 113 is formed on the surface of the first metal silicide layer 112, the surface of the through via contact metal layer 113 is flush with the top surface of the dielectric layer 105. In some implementations, the material of the through via contact metal layer is different from the material of the first metal layer.

The material of the first metal layer is one or more nickel, cobalt, tantalum, or titanium. The formation process of the first metal layer is sputtering, and the thickness of the first metal layer is less than the radius of the channel through via.

The annealing includes a first annealing and a second annealing performed at one time, and the temperature of the second annealing is higher than the temperature of the first annealing. In an implementation, the first annealing is immersion annealing, the annealing temperature is 220-320° C., and the annealing duration is 30-90 seconds. The second annealing is millisecond annealing, and the annealing temperature is 700-950 C °, and the annealing duration is 0.25-20 milliseconds.

A wet etching process may be adopted to remove the unreacted first metal layer.

The material of the formed first metal silicide layer 112 is one or a combination of nickel silicide, cobalt silicide, tantalum silicide, or titanium silicide. In some implementations of the present disclosure, the step of forming the first metal silicide layer 112 and the subsequent step of forming the second metal silicide layer are not performed in the same step, and therefore, by separately adjusting the thickness of the first metal layer, the thickness of the formed first metal silicide layer 112 may be adjusted separately such that the thickness of the first metal silicide layer is not limited by the process of forming the second metal silicide layer, so that the thickness of the formed first metal silicide layer 112 meets the performance requirements. In an implementation, the thickness of the first metal layer is 7 nm-50 nm, and the thickness of the first metal silicide layer 112 is 7 nm-50 nm.

For example, the formation process of the through via contact metal layer 113 is as follows: a metal layer is formed on the dielectric layer 105 and the first metal silicide layer 112: the metal layer higher than the surface of the dielectric layer 105 is removed by planarization, and a through via contact metal layer 113 is formed on the first metal silicide layer 112. The through via contact metal layer 113 is subsequently used to connect with a bit line, and when the second metal silicide layer is subsequently formed, the through via contact metal layer may isolate the second metal layer from the first metal silicide layer 112, preventing the thickness of the formed first metal silicide layer 112 from changing. The through via contact metal layer 113 may also be taken as an etching stopping layer when the third through via is subsequently formed in the hard mask layer. In some implementations, the through via contact metal layer 113 is a bit line contact plug. The subsequently formed bit line contact is in conductive contact with the first metal silicide layer through the bit line contact plug. In the implementations of the present disclosure, the bit line contact plug is formed in the channel through via without using an additional mask layer to form the bit line contact plug.

For example, the material of through via contact metal layer 113 may be tungsten.

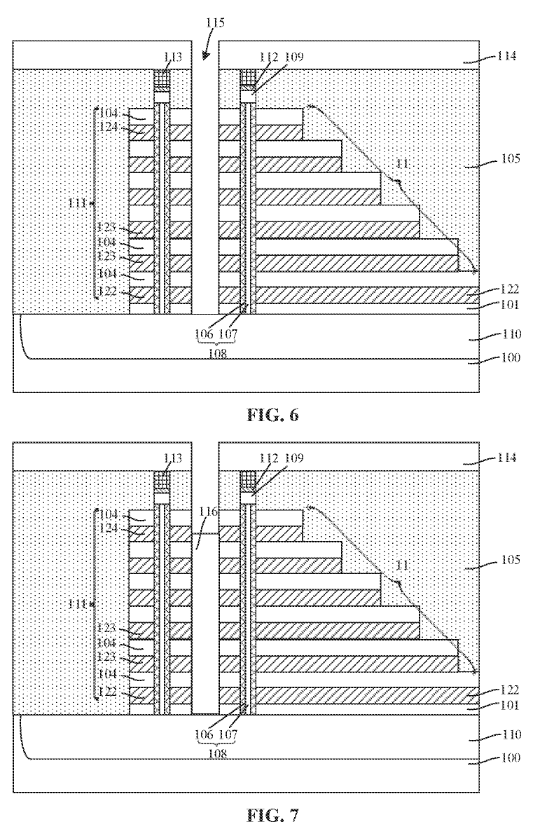

Referring to FIG. 6, the sacrificial layer is replaced with a gate line 123.

In an implementation, the formation process of the gate line 123 is as follows: a hard mask layer 114 is formed on the stacked structure 111; a gate line slit 115 is formed in the hard mask layer 114 and the stacked structure 111; the sacrificial layer is removed along the gate line slit 115; the gate line 123 is formed at a position where the sacrificial layer is removed.

In some examples, after the gate line slit 115 is formed, the method further includes removing the hard mask layer 114 and forming a second dielectric layer on the dielectric layer 105. For example, the position of the second dielectric layer is the same as the position of the hard mask layer 114 in FIGS. 6-10. Since the position of the second dielectric layer is the same as the position of the hard mask layer 114 in FIGS. 6-10 (that is, the hard mask layer 114 in FIGS. 6-10 is replaced with the second dielectric layer), additional drawings are no longer provided to illustrate the structure of the second dielectric layer and the structure of the memory including the second dielectric layer. For example, the second dielectric layer includes silicon oxide (e.g., the second dielectric layer is silicon oxide).

For example, the hard mask layer 114 may be a single layer or a multilayer stacked structure. For example, the material of the hard mask layer 114 is one or more of silicon oxide, silicon nitride, silicon oxynitride, and silicon carbide.

A wet etching process is adopted to remove the sacrificial layer. In an implementation, a bottom selective gate (BSG) 122 may be formed at a corresponding position after the bottommost layer of the sacrificial layer (bottom selective gate sacrificial layer) in the stacked structure is removed correspondingly, and a top selective gate (TSG) 124 may be formed at a corresponding position after the topmost layer of the sacrificial layer (top selective gate sacrificial layer) in the stacked structure is removed correspondingly. The bottom selective gate sacrificial layer and the top selective gate sacrificial layer are removed at the same time as other sacrificial layers, and the bottom selective gate 122 and the top selective gate 124 are formed at the same time as the gate line 133.

The gate line 123 includes a gate dielectric layer and a gate electrode located on the gate dielectric layer. In an implementation, the gate line 123 may be a high-K dielectric layer and a metal gate located on the surface of the high-K dielectric layer, and the material of the metal gate may be one or more of W, Al, Cu, Ti, Ag, Au, Pt, and Ni. The material of the high-K dielectric layer is HfO2, TiO₂. HfZrO, HfSiNO, Ta₂O₅, ZrO₂. ZrSiO₂. AI₂O₃. SrTiO₃, or BaSrTiO. In other implementations, the gate line 123 may include a silicon oxide dielectric layer and a polysilicon gate located on the dielectric layer.

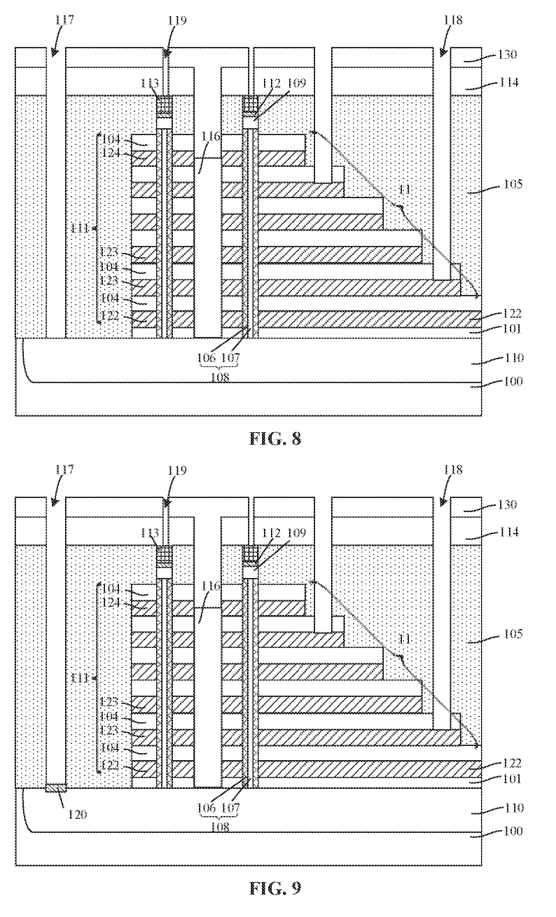

Referring to FIG. 7, an array common source (ACS) 116 is formed in the gate line slit (GLS) 115 (as shown in FIG. 6).

Before forming the array common source 116, an isolation spacer is formed on the sidewall of the gate line slit 115. The isolation spacer includes an electrical isolation layer (e.g., a dielectric layer) deposited on the sidewall of the gate line slit 115. For example, the array common source (ACS) 116 includes a conductive layer of conductive materials such as titanium nitride, W, Co. Cu, Al, doped silicon, or silicide, and the electrical isolation layer may be an insulating material layer such as a silicon oxide layer.

In some implementations of the present disclosure, the surface where the array common source 116 is formed is lower than the surface of the hard mask layer 114, and the material of the array common source 116 is a polysilicon layer

Referring to FIG. 8, a patterned photoresist layer 130 is formed on the hard mask layer 114: the hard mask layer 114 and the dielectric layer 105 are etched by taking the patterned photoresist layer 130 as a mask. A first through via 117 exposing part of the surface of the well region 110 on one side of the stacked structure 111 and a number of second through vias 118 exposing the surface of the corresponding staircase structure 11 are formed in the hard mask layer 114 and the dielectric layer 105, and a third through via 119 exposing a part of the surface of the through via contact metal layer 113 is formed in the hard mask layer 114. the size of the third through via 119 is less than the size of the through via contact metal layer 113.

A first contact plug connected to the well region 110 is subsequently formed in the first through via 117, a second contact plug connected to the staircase structure 11 is subsequently formed in the second through via 118, a bit line contact (Bit Line contact) connected to the through via contact metal layer 113 is subsequently formed in the third through via 119. The thickness of the through via contact metal layer (bit line contact plug) is less than the thickness of the bit line contact.

The size of the third through via 119 is less than the size of the through via contact metal layer 113 (or channel through via), and the diameter of the corresponding bit line contact subsequently formed is less than that of the through via contact metal layer 113 (or channel through via), such that the diameter of the formed bit line contact smaller. In an implementation, the diameter of the third through via 119 may be ¼-⅔ of the diameter of the through via contact metal layer 113 (or the channel through via).

For example, the hard mask layer 114 and the dielectric layer 105 may be etched by an anisotropic dry etching process, such as an anisotropic plasma etching process. Here, the materials of the hard mask layer and the dielectric layer are the same.

In some implementations of the present disclosure, since the first metal silicide layer 112 is formed first and then the second metal silicide layer is formed, in this way, the thickness of the first metal silicide layer 112 may be individually controlled to meet performance requirements. For example, when forming the first metal silicide layer 112, there is no need to form a mask layer (the position of the first metal silicide layer 112 is directly limited by the channel through via), and the second metal silicide layer and the first contact plug, the second contact plug and the bit line contact only need to be formed by a photolithography process once, and a bit line contact with a smaller diameter may be formed through one photolithography process, thereby saving costs.

In some implementations of the present disclosure, since the first metal silicide layer 112 is formed first, and then the second metal silicide layer is formed, such that the thickness of the first metal silicide layer 112 may be individually controlled. For example, the thickness of the first metal silicide layer and the thickness of the second metal silicide layer may also be made the same.

In some implementations of the present disclosure, the first metal silicide layer 112 is formed first and then the second metal silicide layer is formed. As such, not only the thickness of the first metal silicide layer 112 may be individually controlled to meet the performance requirements, but also when the first through via 117 and the third through via 119 are formed through the hard mask layer 114, since the first metal silicide layer 112 has already been formed, the size of the third through via 119 will not affect the size of the first metal silicide layer. Therefore, the size of the third through via 119 may be set to be smaller than the size of the through via contact metal layer 113 (or the channel through via) at this time. As such, a bit line contact with a size smaller than that of the through via contact metal layer 113 (or channel through via) may be formed by forming the hard mask layer 114 of the second metal silicide layer. Therefore, the second metal silicide layer and the first contact plug, the second contact plug, and the bit line contact only need to be formed by a photolithography process once, and a bit line with a smaller size may be formed through a photolithography process, thereby saving cost.

In the method in which the first metal silicide layer and the second metal silicide layer are formed in the same process step in the related art, a photolithography process is used when the first metal silicide layer and the second metal silicide layer are formed. Only the bit line contact plug can be formed in the photolithography process. A photolithography process is required to form a bit line contact smaller in size than the bit line contact plug. However, in the implementations of the present disclosure, since the first metal silicide layer and the bit line contact plugs in contact with the first metal silicide layer have been formed before the photolithography process of forming the second metal silicide layer, in the photolithography process of forming the second metal silicide layer, a third through via 119 with a size smaller than that of the first metal silicide layer or the bit line contact plug may be formed, and a bit line contact may be formed through the third through via 119. In other words, compared with the related art, in the implementations of the present disclosure, the first metal silicide layer and the through via contact metal layer (ie, the bit line contact plug) may be formed only through the Recess process, without using a mask layer, and the bit line contact may be formed only through photolithography process once.

Referring to FIG. 9, a second metal silicide layer 120 is formed on the surface of the well region at the bottom of the first through via 117.

In an implementation, the formation process of the second metal silicide layer 120 includes as follows: a second metal layer is formed in the first through via 117 and the surface of the hard mask layer 114; the annealing is performed to make the second metal layer reacts with the silicon in the well region to form a second metal silicide layer 120 on the surface of the well region: the unreacted second metal layer is removed. It is to be noted that when the second metal layer is deposited in the first through via 117, the second metal layer usually exists on the surface of the hard mask layer 114.

The material of the second metal layer is one or more of nickel, cobalt, tantalum, and titanium. The formation process of the second metal layer is sputtering.

The annealing includes a first annealing and a second annealing performed at one time, and the temperature of the second annealing is higher than the temperature of the first annealing. In an implementation, the first annealing is immersion annealing, the annealing temperature is 220-320° C., and the annealing duration is 30-90 seconds. The second annealing is millisecond annealing, the annealing temperature is 700-950° C., and the annealing duration is 0.25-20 milliseconds.

A wet etching process may be adopted to remove the unreacted first metal layer.

The material of the formed first metal silicide layer 112 is one or a combination of nickel silicide, cobalt silicide, tantalum silicide, and titanium silicide.

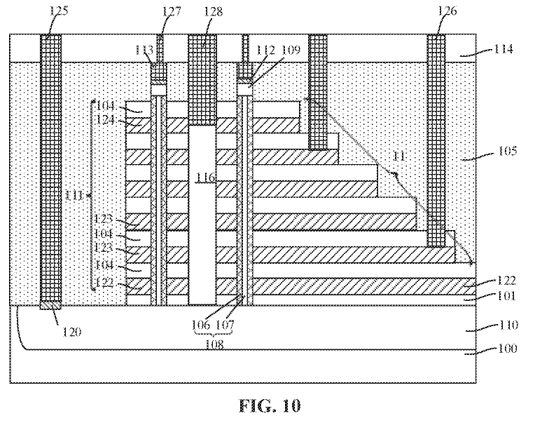

Referring to FIG. 10, a first contact plug 125 connected to the second metal silicide layer 120 is formed in the first through via, a second contact plug 126 connected to the surface of the corresponding staircase structure 11 is formed in the second through via, and a bit line contact 127 connected to the through via contact metal layer 113 is formed in the third through via.

The first contact plug 125, the second contact plug 126, and the bit line contact 127 are formed in the same step. Before the first contact plug 125, the second contact plug 126, and the bit line contact 127 are formed, the patterned photoresist layer 130 is removed to expose the remaining gate line slit on the array common source 116, a fourth contact plug 128 is formed in the remaining gate line slit on the array common source 116, while forming the first contact plug 125, the second contact plug 126 and the bit line contact 127. The fourth contact plug may be used to electrically extract the array common source, so the fourth contact plug may be referred to as a source contact plug.

In some implementations, the formation process of the first contact plug 125, the second contact plug 126, the bit line contact 127, and the fourth contact plug 128 is as follows. A metal layer is formed that fills the first through via, the second through via, the third through via, and the remaining gate line slit on the array common source 116 and covers the surface of the hard mask layer 114. The material of the metal layer may be tungsten. The metal layer higher than the surface of the hard mask layer 114 is removed by a planarization process (such as a chemical mechanical polishing process). A first contact plug 125 is formed in the first through via. A second contact plug 126 is formed in the second through via, and a bit line contact 127 is formed in the third through via. A fourth contact plug 128 is formed in the remaining gate line slit on the array common source 116.

For example, compared to the method in which the first metal silicide layer and the second metal silicide layer are formed in the same process step in the related art, in the method for forming the 3D NAND memory device of the present disclosure, the first metal silicide layer 112 has already been formed before the first through via 117 and the third through via 119 are formed, and therefore, the diameter of the third through via (bit line contact) may be controlled by the photolithography process of forming the first through via. As the memory integration becomes higher and higher, the size of the memory cell will become smaller and smaller, and the diameter of the bit line contact may be controlled by the method provided by the implementations of the present disclosure, in other words, the diameter of the bit line contact may be freely controlled by the method provided by the implementations of the present disclosure, so that the diameter of the bit line contact may be adapted to smaller and smaller memory cells.

Furthermore, compared with the related art in which two photolithography processes are required, that is, a layer of mask layer and a layer of a second dielectric layer need to be formed to form the bit line contact plug (located in the mask layer) and the bit line contact (located in the second dielectric layer), in the present disclosure, the photolithography process is required only once, that is, only one hard mask layer is formed to form the bit line contact plug (located in the channel through via) and the bit line contact (located in the hard mask layer or the second dielectric layer). As a result, the longitudinal height of the 3D NAND memory device (referring to FIG. 1D) finally formed in the related art is greater than the longitudinal height of the 3D NAND memory device (referring to FIG. 10) finally formed in the present disclosure. In other words, by the method for forming the 3D NAND memory device provided by the present disclosure, the longitudinal size of the device may be reduced.

The implementations of the present disclosure further provide a memory. The memory includes a semiconductor layer, a stacked structure, a dielectric layer, a channel hole, a second metal silicide layer, and a first contact plug. The stacked structure is located on the semiconductor layer, and the dielectric layer covers the semiconductor layer and the stacked structure; the channel hole penetrates through the stacked structure, and includes a channel structure, a polysilicon layer, a first metal silicide layer, and a through via contact metal layer located on the first metal silicide layer; the second metal silicide layer and the first contact plug are formed in the dielectric layer, the second metal silicide layer is located on the semiconductor layer, and the first contact plug is located on the second metal silicide layer; the through via contact metal layer is a bit line contact plug.

In some implementations, the diameter of the through via contact metal layer is equal to the diameter of the polysilicon layer.

In some implementations, the memory further includes: a second dielectric layer located on the dielectric layer; a bit line contact located within the second dielectric layer. The bit line contact is located on the through via contact metal layer, and the diameter of the bit line contact is less than the diameter of the channel hole.

In some implementations, the thickness of the through via contact metal layer is less than the thickness of the bit line contact.

In some implementations, the diameter of the bit line contact is less than the diameter of the first contact plug.

In some implementations, the end of the stacked structure has a staircase structure; the memory further includes a second contact plug. The second contact plug is located in the dielectric layer, the second contact plug is connected to the surface of the corresponding staircase structure, and the diameter of the second contact plug is greater than the diameter of the bit line contact.

In some implementations, the memory further includes: an array common source and a fourth contact plug that are located in a stacked structure. The array common source is located on the semiconductor layer, and the fourth contact plug is located on the array common source.

The implementations of the present disclosure further provide a storage system. The storage system includes: a memory as described above; and a storage controller that is coupled to the memory.

In some implementations, the memory may specifically be a 3D NAND memory device.

In some implementations, the storage system may be a device with a memory, such as an electronic computer, a smartphone, a smart TV, a smart set-top box, a smart router, an electronic digital camera, or an SSD. The storage system of the present disclosure generally also includes a controller, an input/output apparatus, a display apparatus, and the like. The memory is used to store files or data and can be invoked by the controller. For example, the storage controller may write data to the memory, that is, the memory provided in the present disclosure, and may also read data from the memory, that is, the memory provided in the present disclosure. The input/output apparatus is used to input instructions or output signals, and the display apparatus visualizes the signals to realize various functions of the storage system.

It is to be noted that the above description of the memory and storage system is similar to the above description in the implementations of the method for forming the 3D NAND memory device, and has similar beneficial effects as the implementations of the method for forming the 3D NAND memory device, and therefore the contents will not be repeated. For technical details not disclosed in the memory and storage system in the implementations of the present disclosure, please refer to the description of the method for forming the 3D NAND memory device in the implementations of the present disclosure for understanding.

The above are only the exemplary implementations of the present disclosure. For those ordinary skilled in the art, several improvements and modifications may be made without departing from the principles of the present disclosure, and these improvements and modifications should also be considered as the protection scope of the present disclosure.

1. A method for forming a 3D NAND memory device, comprising:
providing a semiconductor structure, wherein the semiconductor structure comprises a semiconductor substrate, a stacked structure on the semiconductor substrate, and a dielectric layer covering the semiconductor substrate and the stacked structure;
forming, in the dielectric layer and the stacked structure, channel through vias penetrating through the stacked structure;
forming a channel structure in each channel through via, and sequentially forming a polysilicon layer, a first metal silicide layer located on the polysilicon layer, and a through via contact metal layer located on the first metal silicide layer in the channel structure,
forming a first through via in the dielectric layer for exposing the semiconductor substrate after forming the first metal silicide layer;
forming a second metal silicide layer at a bottom of the first through via; and
forming a first contact plug connected to the second metal silicide layer in the first through via.

2. The method for forming the 3D NAND memory device of claim 1, wherein forming the first metal silicide layer and the through via contact metal layer comprises:
forming a first metal layer on a surface of the dielectric layer and on the polysilicon layer in the channel through via;
annealing the first metal layer to make the first metal layer react with part of the polysilicon layer in the channel structure to form a first metal silicide on a surface of the polysilicon layer, wherein a surface of the first metal silicide layer is lower than a top surface of the dielectric layer; and
removing the unreacted first metal layer and forming the through via contact metal layer on the surface of the first metal silicide layer, wherein a surface of the through via contact metal layer is flush with the top surface of the dielectric layer.

3. The method for forming the 3D NAND memory device of claim 2, wherein forming the first metal silicide layer comprises forming the first metal silicide layer using one or a combination of nickel silicide, cobalt silicide, tantalum silicide, or titanium silicide.

4. The method for forming the 3D NAND memory device of claim 1, wherein forming the stacked structure comprises alternately stacking sacrificial layers and isolation layers, after forming the through via contact metal layer, the method further comprises: replacing the sacrificial layers with gate lines.

5. The method for forming the 3D NAND memory device of claim 4, wherein forming the gate lines comprises: forming a hard mask layer on the stacked structure: forming a gate line slit in the hard mask layer and the stacked structure, removing the sacrificial layers along the gate line slit; forming gate lines at positions where the sacrificial layers are removed; and forming an array common source in the gate line slit.

6. The method for forming the 3D NAND memory device of claim 5,wherein forming the hard mask layer comprises forming the hard mask layer using the same material as the dielectric layer.

7. The method for forming the 3D NAND memory device of claim 5, further comprising: forming a bit line contact connected to the through via contact metal layer in the hard mask layer, wherein a size of the bit line contact is less than a size of the through via contact metal layer.

8. The method for forming the 3D NAND memory device of claim 7, wherein an end of the stacked structure has a staircase structure, when forming the first through via in the dielectric layer, the method further comprises: forming a second through via in the dielectric layer for exposing a surface of corresponding staircase structure.

9. The method for forming the 3D NAND memory device of claim 8,further comprising: forming a second contact plug connected to the surface of the corresponding staircase structure in the second through via.

10. The method for forming the 3D NAND memory device of claim 9, wherein forming the second metal silicide layer, the first contact plug, the second contact plug, and the bit line contact comprises:
etching the hard mask layer and the dielectric layer;
forming, in the hard mask layer and the dielectric layer, the first through via exposing the semiconductor substrate on one side of the stacked structure and the second through via exposing a surface of corresponding staircase structure;
forming, in the hard mask layer, a third through via exposing a part of a surface of the through via contact metal layer, wherein a size of the third through via is less than a size of the channel through via;
forming a second metal layer in the first through via and on a surface of the hard mask layer;
performing annealing to make the second metal layer react with silicon in the semiconductor substrate to form a second metal silicide layer on a surface of the semiconductor substrate:
removing the unreacted second metal layer;
filling the first through via, the second through via, and the third through via with a metal layer:
forming a first contact plug connected to the second metal silicide layer in the first through via;
forming, in the second through via, a second contact plug connected to a surface of the corresponding staircase structure; and
forming, in the third through via, a bit line contact connected to the through via contact metal layer.

11. The method for forming the 3D NAND memory device of claim 7, wherein a material of the second metal silicide layer is one or a combination of nickel silicide, cobalt silicide, tantalum silicide, or titanium silicide.

12. The method for forming the 3D NAND memory device of claim 5, wherein forming the channel structure comprises forming a charge storage layer located on a sidewall surface of the channel through via and a channel layer located on a sidewall surface of the charge storage layer, wherein
the charge storage layer comprises a barrier layer located on the sidewall surface of the channel through via, a charge trapping layer located on a sidewall surface of the barrier layer, and a tunneling layer on the sidewall surface of the charge trapping layer:
each gate line comprises a gate dielectric layer and a gate electrode located on the gate dielectric layer; and
the through via contact metal layer is a bit line contact plug.

13. The method for forming the 3D NAND memory device of claim 1, wherein the first contact plug and an orthographic projection of the stacked structure on the semiconductor substrate do not overlap.

14. A memory device, comprising:
a semiconductor layer, a stacked structure located on the semiconductor layer, and a dielectric layer covering the semiconductor layer and the stacked structure:
a channel hole, penetrating through the stacked structure, wherein the channel hole comprises a channel structure, a polysilicon layer, a first metal silicide layer, and a through via contact metal layer located on the first metal silicide layer: and
a second metal silicide layer and a first contact plug formed in the dielectric layer, wherein the second metal silicide layer is located on the semiconductor layer, and the first contact plug is located on the second metal silicide layer,
wherein the through via contact metal layer is a bit line contact plug.

15. The memory device of claim 14, wherein a diameter of the through via contact metal layer is equal to a diameter of the polysilicon layer.

16. The memory device of claim 15, further comprising:
a second dielectric layer located on the dielectric layer; and
a bit line contact located within the second dielectric layer, wherein the bit line contact is located on the through via contact metal layer, a diameter of the bit line contact is less than a diameter of the channel hole.

17. The memory device of claim 16, wherein a thickness of the through via contact metal layer is less than a thickness of the bit line contact.

18. The memory device of claim 16, wherein a diameter of the bit line contact is less than a diameter of the first contact plug.

19. The memory device of claim 16, wherein an end of the stacked structure has a staircase structure, the memory device further comprises: a second contact plug, located in the dielectric layer, wherein the second contact plug is connected to a surface of a corresponding staircase structure, and a diameter of the second contact plug is greater than a diameter of the bit line contact.

20. A storage system, comprising: a memory; and a storage controller coupled to the memory, wherein the memory comprises:
a semiconductor layer, a stacked structure located on the semiconductor layer, and a dielectric layer covering the semiconductor layer and the stacked structure;
a channel hole, penetrating through the stacked structure, wherein the channel hole comprises a channel structure, a polysilicon layer, a first metal silicide layer, and a through via contact metal layer located on the first metal silicide layer: and
a second metal silicide layer and a first contact plug formed in the dielectric layer, wherein the second metal silicide layer is located on the semiconductor layer, and the first contact plug is located on the second metal silicide layer,
wherein the through via contact metal layer is a bit line contact plug.
